(19) United States
(12) Patent Application Publication
(10) Pub. No.: US 2004/0050495 A1
(43) Pub. Date: Mar. 18, 2004

(54) Plasma processing apparatus and plasma processing method

(76) Inventors: Masahiro Sumiya, Kudamatsu-shi (JP); Naoki Yasui, Kudamatsu-shi (JP); Tomoyuki Tamura, Kudamatsu-shi (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/364,464

(22) Filed: Feb. 12, 2003

(30) Foreign Application Priority Data
Sep. 13, 2002 (JP) 2002-268095

(51) Int. Cl. C23C 16/00; C23F 1/00

(52) U.S. Cl. 156/345.48; 156/345.28; 118/723 AN; 118/712

(57) ABSTRACT

A plasma processing apparatus comprising a processing chamber 102 to which is connected an exhaust pump 124 for decompressing the chamber, a gas feeding apparatus 107 for feeding gas into the processing chamber 102, an object 116 to be processed, a wafer electrode 115 for mounting the object 116, an antenna electrode 103 for generating plasma and opposed to the plate electrode 115, a plasma generating high frequency power supply 111 connected to the antenna electrode 103, a first high frequency power supply 119 connected to the wafer electrode 115, and a second high frequency power supply 114 connected to the antenna electrode 103, further comprising a phase control means 122 for controlling the phase difference of high frequencies applied from the first high frequency power supply 119 and the second high frequency power supply 114 and having the same frequency, according to which the phase of the high frequencies from the first and second power supplies are varied by 180°.

### FIELD OF THE INVENTION

The present invention relates to a plasma processing apparatus and plasma processing method, and more specifically, to a plasma processing apparatus and plasma processing method preferable for treating with plasma the surface of a sample such as a semiconductor element.

### DESCRIPTION OF THE RELATED ART

When plasma is used to perform an etching treatment, process gas is ionized and activated to increase the process speed, and high frequency bias power is applied to the object to be etched so that the ions existing within the plasma are injected perpendicularly on the object, according to which highly accurate etching (for example, anisotropic etching) is made possible.

One example of a conventional plasma processing apparatus for etching consists of a vacuum vessel, a solenoid coil provided to the outer periphery of the exterior of the vacuum vessel, and a circular conductive plate arranged opposite to a sample stage provided within the vacuum vessel. It further consists of a UHF-bandpower supply and another high frequency power supply connected to the circular conductive plate and a high frequency power supply connected to the sample stage. The apparatus characterized in superposing and applying to the circular conductive plate an electric field of an UHF-band frequency generating plasma by the interaction between the electromagnetic wave from the UHF-band power supply and the magnetic field from the solenoid coil and an electric field of a frequency different from the UHF-band frequency, having the circular conductive plate (made for example of Si) react with plasma, thereby creating more active species that contribute to the etching process. The incident energy of ions to the wafer is controlled by high frequency power supply connected to the sample stage (refer for example to patent documents 1 or 2).

The conventional plasma processing apparatus comprises a processing chamber, as shown in FIG. 4, a vacuum vessel 101 sealing a processing vessel 102, an antenna electrode 103 and a dielectric window 104. A coil 105 for generating a magnetic field is disposed to surround the processing chamber to the outer periphery of the processing vessel 102. The antenna electrode 103 has a porous (shower head) structure allowing etching gas to flow through, and is connected to a gas feeding apparatus 107. Further, an exhaust pump 124 is connected to the vacuum vessel 101.

Above the antenna electrode 103 is provided a coaxial waveguide 108, and via the coaxial waveguide 108, a filter 109 and a matching unit 110, a UHF-band power supply 111 for generating plasma is connected to the electrode 103. Moreover, via the coaxial waveguide 108, a filter 112 and a matching unit 113, the other high frequency power supply 114 is connected to the antenna electrode 103.

A wafer electrode 115 for mounting the object 116 to be processed is located at the bottom of the vacuum vessel 101. The wafer electrode 115 is connected via a filter 117 and a matching unit 118 to a high frequency power supply 119. Moreover, the wafer electrode 115 is connected via a filter 120 to an electrostatic chuck power supply 121 for electrostatically chucking the object 116 to the electrode head.

Patent Document 1:

Japanese Patent Laid-Open Publication No. 9-321031

Patent Document 2:

U.S. Pat. No. 5,891,252

Recently, along with the increase of the integration of the semiconductor integrated circuit, the use of a large-diameter wafer (12 inches) is becoming more and more popular in the production site, so as to enhance throughput. Therefore, it has become an urgent task to improve the uniformity of the processing.

Moreover, in the conventional apparatuses, ions are accelerated by the electric field between the grounded vacuum vessel and the plasma potential. This may cause sputtering of the inner walls of the vacuum vessel by the ions, which results in increase of particles.

Further, along with the increase in the integration degree of semiconductor devices, there is increasing demand for improving the mask selectivity for high-precision surface treatment, and in order to do so, it is very important to create a desirable plasma composition.

### SUMMARY OF THE INVENTION

The first object of the present invention is to provide a plasma processing apparatus and plasma processing method capable of increasing the uniformity of the plasma processing.

The second object of the present invention is to provide a plasma processing apparatus and plasma processing method capable of reducing the amount of particles being generated.

The third object of the present invention is to provide a plasma processing apparatus and plasma processing method capable of providing a high-precision surface treatment.

The first object of the present invention is achieved by providing an electrode that opposes to the wafer electrode on which the sample is disposed, applying high frequency power for generating plasma on the opposing electrode, and applying to each of the electrodes, respectively, a high frequency power having a lower frequency than the high frequency power for generating plasma and with a controlled phase. Further, the phase difference of the high frequency applied to each of the electrodes ranges from 0° to 360°. Moreover, plasma is generated by the high frequency power and magnetic field. Even further, it is effective to switch the phase by multiple steps or to modulate the phase with time.

The second object of the present invention is achieved by providing an electrode that opposes to the wafer electrode on which the sample is disposed, applying high frequency power for generating plasma to the opposing electrode, and applying to each of the electrodes, respectively, a high frequency power having a lower frequency than the high frequency power for generating plasma and with a phase difference controlled to 180°±45°. Moreover, it is further effective to provide a cover and a film containing carbon to the inner walls of the processing chamber.

The third object of the present invention is achieved by providing an electrode that opposes to the wafer electrode on which the sample is disposed, applying high frequency power for generating plasma on the opposing electrode, and applying to each of the electrodes, respectively, a high frequency power having a lower frequency than the high frequency power for generating plasma and with a controlled phase. Further, the phase difference of the high frequency applied to each of the electrodes is in the range of 0° to 360°. Moreover, it is further effective to provide a cover and a film containing carbon to the inner walls of the processing chamber.

### BRIEF DESCRIPTION OF THE DRAWINGS

FIG. 1 is a vertical cross-sectional view showing an etching apparatus according to the first embodiment of the present invention;

FIG. 2 is a characteristic chart showing the relationship between the etching distribution and the phase difference of the high frequency voltage;

FIG. 3 is a characteristic chart showing the relationship between the maximum voltage of the wafer electrode and the phase difference of the high frequency voltage;

FIG. 4 is a vertical cross-sectional view showing the etching apparatus according to the conventional method;

FIG. 5 is a chart showing the plasma potential and electrode voltage waveform according to the conventional system and the present invention;

FIG. 6 is a conceptual diagram showing the plasma diffusion according to the conventional system and the present invention utilizing a polyimide cover and a polyimide coating;

FIG. 7 is a chart showing the relationship between the process lot number and the number of particles according to the conventional system and the present invention;

FIG. 8 is a characteristic chart showing the plasma composition and the phase difference of the high frequency voltage; and

FIG. 9 is a vertical cross-sectional view showing the etching apparatus according to the second embodiment of the present invention.

### DETAILED DESCRIPTION OF THE PREFERRED EMBODIMENT

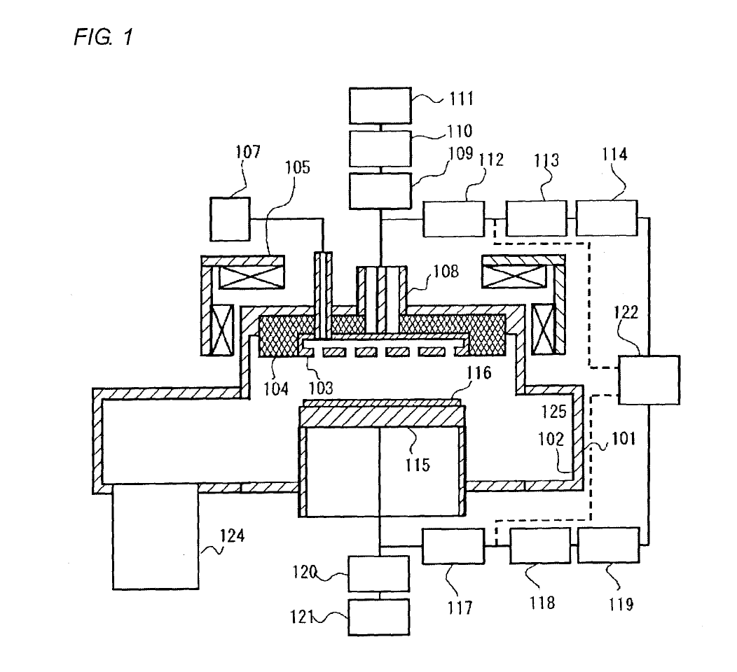

Now, the first preferred embodiment of the present invention will be explained with reference to FIGS. 1 through 8. FIG. 1 is a vertical cross-sectional view of an etching apparatus which is one example of a plasma processing apparatus to which the present invention is applied. On the upper opening portion of a vacuum vessel 101 are disposed a cylindrical processing vessel 102, sealed with a plate-shaped antenna electrode 103 formed of a conductive material and a dielectric window 104 allowing electromagnetic waves to pass through, and a processing chamber is formed. A coil 105 for generating magnetic field is disposed to the outer periphery of the processing vessel 102 surrounding the processing chamber. The antenna electrode 103 has a shower head structure allowing etching gas to flow through, to which is connected a gas feeding apparatus 107. Further, an exhaust pump 124 is connected to the vacuum vessel 101.

A coaxial waveguide 108 is provided above the antenna electrode 103, and via the coaxial waveguide 108, a filter 109 and a matching unit 110, a high frequency power supply 111 for generating plasma (having a frequency of 450 MHz, for example) is connected to the antenna electrode 103. Further, an antenna bias power supply (second high frequency power supply) 114 (having a frequency between 400 KHz and 4 MHz, for example) is connected to the antenna electrode 103 via the coaxial waveguide 108, a filter 112 and a matching unit 113. The filter 109 transmits the high frequency power supplied from the high frequency power supply 111 and effectively cuts the bias power from the antenna bias power supply 114. The filter 112 transmits the bias power supplied from the antenna bias power supply 114 and effectively cuts the high frequency power supplied from the high frequency power supply 111.

A wafer electrode 115 for mounting the object 116 to be processed is disposed to the lower portion of the vacuum vessel 101. A wafer bias power supply (first high frequency power supply) 119 (having a frequency of 400 kHz to 4 MHz, for example) is connected to the plate electrode 115 via a filter 117 and a matching unit 118. Further, an electrostatic chuck power supply 121 is connected to the wafer electrode 115 via a filter 120 for electrostatically attracting the object 116 to the plate electrode. The filter 117 transmits the bias power from the wafer bias power supply 119 and effectively cuts the high frequency power provided from the high frequency power supply 111. Normally, high frequency power is absorbed in the plasma and will not flow toward the wafer electrode 115. The filter 120 transmits the DC power supplied from the electrostatic chuck power supply 121, and effectively cuts the power from the high frequency power supply 111, the antenna bias power supply 114 and the wafer bias power supply 119.

The antenna bias power supply 114 and the wafer bias power supply 119 are connected to a phase controller 122, by which the phase of the high frequency output from the antenna bias power supply 114 and that output from the wafer bias power supply 119 can be controlled. In the example, the frequencies of the antenna bias power supply 114 and the plate bias power supply 119 are the same.

The phase controller 122 takes in voltage waveforms from between the filter 112 and matching unit 113 of the antenna bias power supply 144 and between the filter 117 and matching unit 118 of the plate bias power supply 119, and outputs small amplitude signals with a varied phase to the antenna bias power supply 114 and the wafer bias power supply 119 so that the voltage waveforms have a desired phase difference in the phase controller 122. In this case, the antenna bias power supply 114 and the wafer bias power supply 119 may only be equipped with an amplifying function.

If the phase controller 122 is designed to take in voltage waveforms from between the filter 112 and matching unit 113 of the antenna bias power supply 114 and between the filter 117 and matching unit 118 of the wafer bias power supply 119 but to only output trigger signals controlling the output timing of the power, the antenna bias power supply 114 and the wafer bias power supply 119 should be equipped with a function as an oscillator. In such case, it is possible to set the phase controller to control the output timings of both the high frequency power supplies or to control only the output timing of one power supply. Moreover, it is possible to set one high frequency power supply to have the function as an oscillator and the other high frequency power supply to have only the function as an amplifier, so that the phase controller 122 can supply to the high frequency power supply having only the amplifying function a small amplitude signal with varied phase based on the output signal of the high frequency power supply having the oscillator function.

In the above-explained apparatus, the interior of the processing chamber is depressurized by the exhaust pump 124, and then etching gas is fed into the processing chamber from the gas supplying apparatus 107 with pressure adjusted to a desired pressure level. The high frequency power having for example a frequency of 450 MHz oscillated by the high frequency power supply 111 is transmitted via the coaxial waveguide 108, through the upper electrode 103 and the dielectric window 104 and introduced to the processing chamber.

The electric field of the high frequency power introduced to the processing chamber interacts with the magnetic field created within the chamber by the magnetic field generating coil 105 (for example, a solenoid coil), and generates high density plasma within the chamber. Further, high frequency power (having a frequency of 400 kHz to 4 MHz, for example) is supplied from the antenna bias power supply 114 via the coaxial waveguide 108 to the antenna electrode 103. Furthermore, high frequency power (having a frequency of 400 kHz to 4 MHz, for example) is supplied from the plate bias power supply 119 to the object 116 to be processed mounted on the plate electrode 115, by which the object is subjected to surface processing (such as etching).

When a desirable material is used to form the antenna electrode 103, the application of high frequency voltage to the antenna electrode 103 by the antenna bias power supply 114 causes the material to react with the radicals within the plasma, thereby controlling the composition of the plasma being generated. For example, in etching an oxide film, Si is used as material of the antenna electrode 103 so as to control the amount of F radicals within the plasma that influences the etching performance of the oxide film.

According to the present apparatus, the high frequency power supply 111 with a frequency of 450 MHz is mainly used to generate plasma, the antenna bias power supply 114 is used to control the plasma composition or the plasma distribution, and the wafer bias power supply 119 is used to control the incident energy of the ions within the plasma to the object 116. Advantageously according to the present invention, the plasma generation (ion quantity) and the plasma composition (ratio of concentration of radicals) can be controlled independently.

According to the conventional system, plasma distribution was mainly adjusted by varying the magnetic field formation and changing the absorption efficiency of UHF electromagnetic waves to the plasma within the plane.

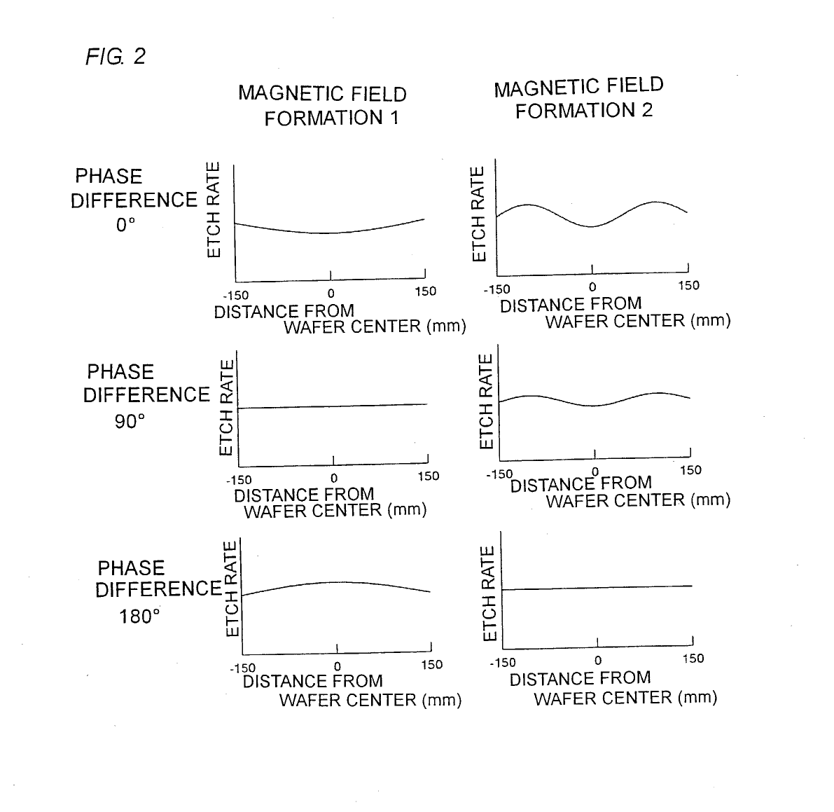

FIG. 2 is referred to in explaining the relationship between the distribution of the etching rate, the phase difference and the magnetic field. In FIG. 2, the vertical axis represents the etching rate and the horizontal axis represents the distance from wafer center. According to FIG. 2, in the case of magnetic field formation 1, the distribution is a gentle convex when the phase difference is 180 degrees, and as the phase difference is changed to 90 degrees and further to zero degrees, the distribution is continuously varied to flat and then to concave. According to magnetic field formation 2, the distribution being flat when the phase difference is 180 degrees is changed to an M-shape distribution as the phase difference is changed to 90 degrees and further to zero degrees. That is, by controlling not only the magnetic field formation but both the magnetic field formation and the phase difference, fine adjustment of the etching distribution is made possible, and the uniformity can be enhanced.

A semiconductor device is generally formed of multilayered films. Therefore, in an etching step, it is necessary to etch multiple layers either at once or by continuous steps. The gas, the ion energy and the ion quantity etc. suitable for etching varies according to the material of the object (films), so in order to etch various layers at once, step etching is performed where the gas and supplied power are varied in steps. When gas species and supplied power are varied, the plasma distribution is changed slightly, so it becomes necessary to control the magnetic field and the like according to each step. However, when magnetic field is used to control plasma distribution, the plasma distribution is varied greatly. According to FIG. 2, phase difference can be utilized to change the plasma distribution slightly, so adjustment using phase difference is most effective in performing very fine adjustment of distribution between each step.

By modulating the phase difference of FIG. 2 with time (for example from phase difference 0° to 180°), substantially the average value of the continuously varying distribution between phase difference 0° and 180° can be obtained (for example, of frequency 1 kHz). Thus, when the phase difference is modulated with time, there is no need to adjust the distribution between etching steps, so the uniformity of etching can be enhanced.

Furthermore, in etching a high aspect ratio hole or a trench, the amount of radicals reaching the bottom of the hole or trench varies according to the aspect ratio and according to the radical species, with respect to the difference in the attachment coefficient of radicals generated in the plasma. The radicals themselves have a lifetime, so the uniformity of radicals on the wafer vary according to radical species. Since the plasma distribution can be varied by phase difference as shown in FIG. 2, by controlling the phase difference according to aspect ratio, a highly uniform processing with a high aspect ratio is made possible.

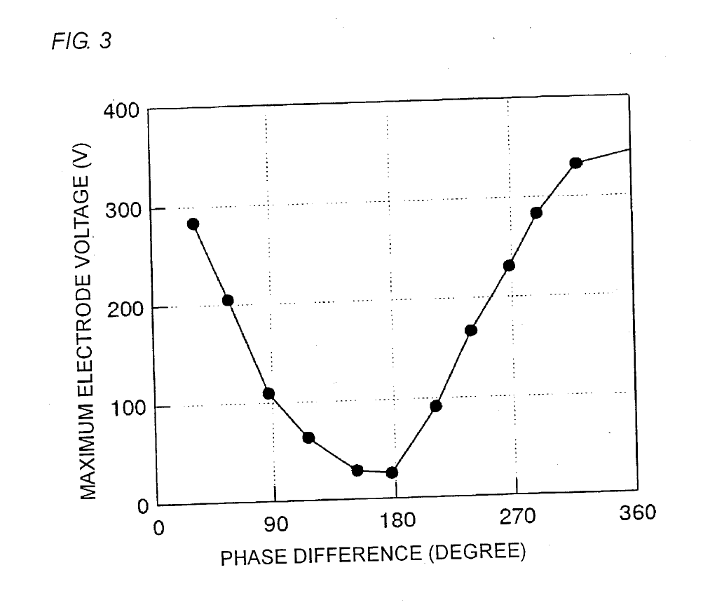

FIG. 3 is referred to in explaining the phase difference and the maximum value of voltage of the object 116 (maximum electrode voltage). In this case, a voltage having an amplitude of approximately 1 kV is applied to the electrode. Generally, the plasma potential is pushed up by this electrode voltage, and ions accelerated by the plasma potential are made incident on the grounded side wall of the processing chamber. By the impact of ions, the inner wall of the processing chamber is sputtered, causing particles to occur. According to FIG. 3, the maximum electrode voltage minimizes when the phase difference is set to 180°, so that by utilizing a phase difference close to 180° the ion energy incident on the side wall is reduced, and sputtering of the side wall is suppressed.

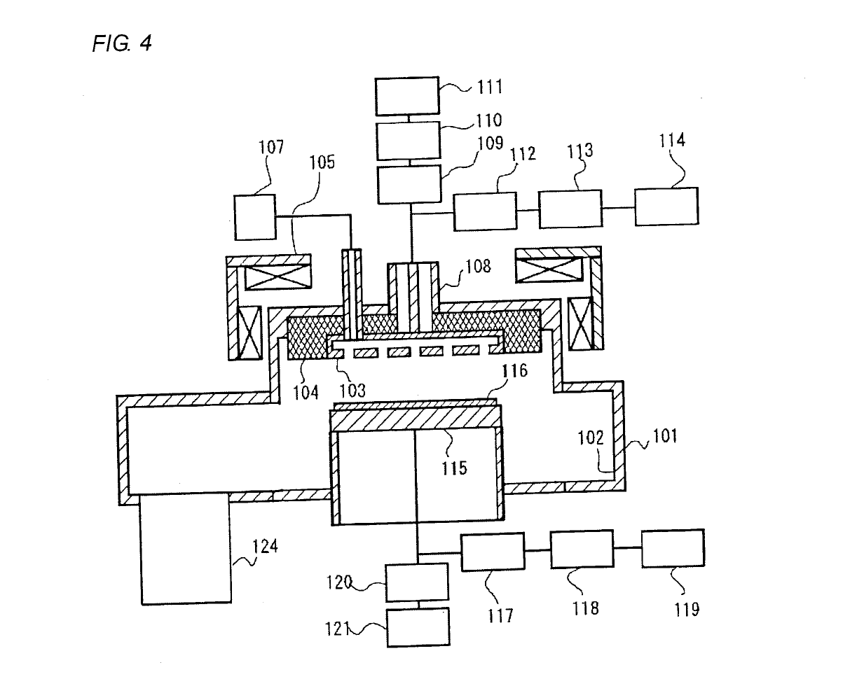

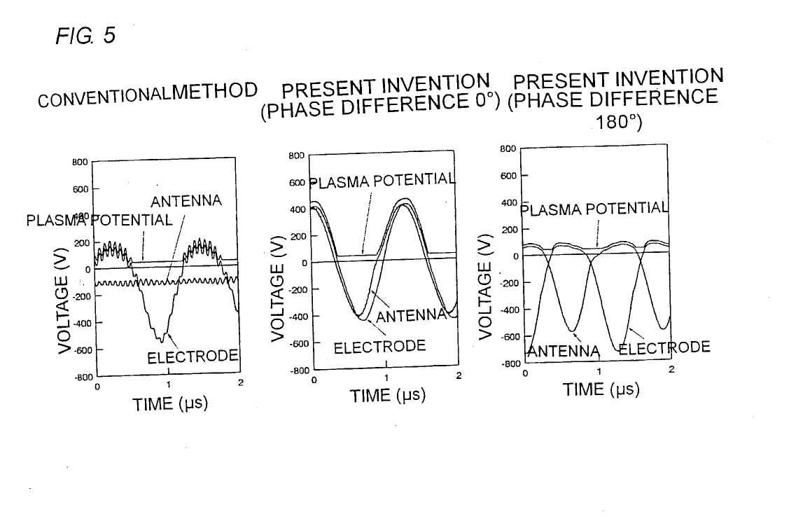

FIG. 5 is used to explain the plasma potential and the electrode potential according to the conventional apparatus shown in FIG. 4 and the apparatus of the present invention. That is, according to the conventional system, the antenna potential of the UHF band is superposed to the electrode potential, and the plasma potential fluctuates in a half-wave rectification waveform with the UHF band ripples being superposed thereto. On the other hand, according to the present invention, when the phase difference between antenna potential and electrode potential is 0°, the plasma potential varies in a half-wave rectification waveform, and when the phase difference is 180°, the plasma potential is maintained to a substantially fixed low level. In this case, the high frequency waveform of the antenna potential (for example, 450 MHz) is superposed to the plasma potential, but causes no problem. The present invention with a phase difference set to 180°±45° is especially effective compared to the conventional apparatus.

When the side wall of the processing chamber is made of aluminum and the surface is treated with alumite (Al₂O₃) processing, by the use of a CF-system etching gas, the alumite film may be sputtered and damaged or AlF may be formed to the surface if the ion energy being incident on the side wall is high. The Al of the component of alumite being sputtered adheres to the wall surface of the processing chamber, reacts with F, and forms AlF. The AlF thus being formed has a low vapor pressure and is stable, so it is often accumulated gradually and becomes the source of particles. The particles caused by AlF are increased as the number of lot processes of the wafer increases and deteriorates the wafer yield factor, so when a certain management limit value is exceeded the processing chamber is released to the atmosphere, and processes such as exchange of parts and wet cleaning are performed. This leads to degraded apparatus operating rate and increases COC such as increased cost for exchange parts.

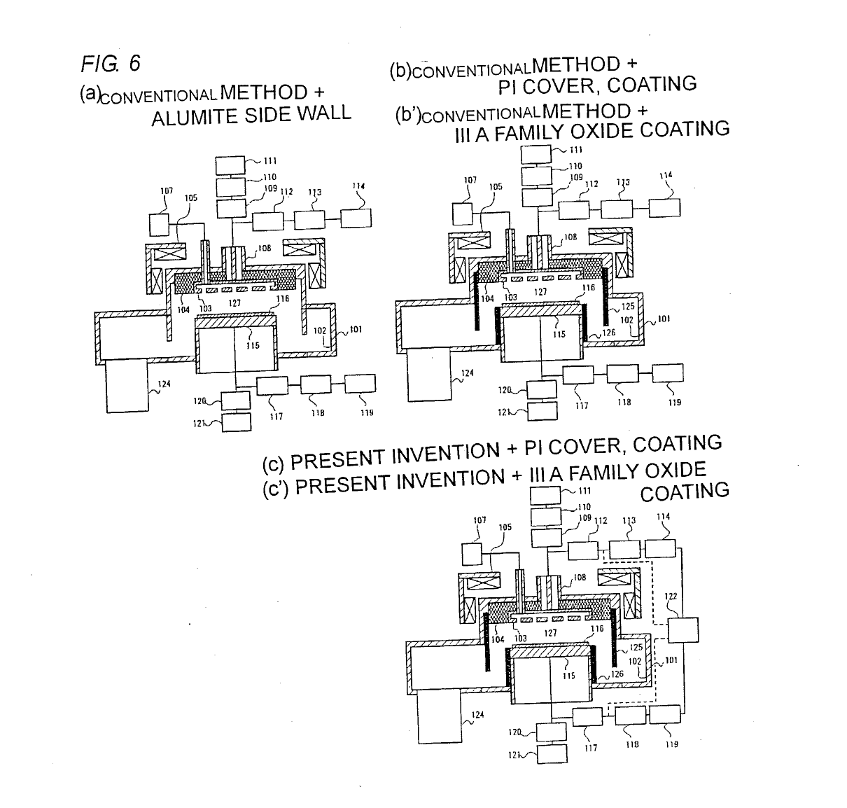

AlF particles can be reduced by not using Al for the inner wall surface of the processing chamber or by reducing the energy of ions being incident on the side walls so as to prevent sputtering thereof. Actual means to realize the former method and to reduce AlF particles is to cover or coat the side walls of the processing chamber with a material including carbon. According to the present embodiment, a polyimide cover and a polyimide coating are used considering their heat resistance. According to the conventional apparatus the plasma potential is high as shown in FIG. 5, so plasma 127 is diffused close to the lower area of the processing chamber as shown in FIG. 6(a). According to the conventional system and applying a polyimide cover and a polyimide coating as insulating material to the side wall of the processing chamber and side wall of the electrode, the plasma 127 is diffused even lower in the processing chamber where earth exists, which is the reference for plasma potential as is shown in FIG. 6(b), (b)′. Since the lower area of the processing chamber is made of alumite, AlF foreign matter is created in that area. However, according to the present invention shown in FIG. 6(c), (c)′ (phase difference 180°), the opposing electrodes alternately function as earth and plasma potential is suppressed low as shown in FIG. 5, so the plasma 127 can be maintained in the higher area of the processing chamber. Thus, the diffusion of plasma 127 toward the alumite material forming the lower portion of the processing chamber is suppressed, and the occurrence of AlF foreign matter is effectively reduced.

Another method for not using Al as the inner wall surface of the processing chamber is to apply as coating a fluoride material having high vapor pressure to the surface of the wall. The material for coating may be an oxide of an element belonging to the III A family of the periodic table, such as scandium, yttrium, lanthanum, cerium, neodymium, ytterbium, dysprosium, and lutetium. Even if the oxide of any of the above element is used in the present invention (phase difference 180°), the opposing electrodes alternately function as earth, suppressing the plasma potential to a low value as shown in FIG. 5, keeping the plasma 127 in the upper area of the processing chamber. Thus, according to the present invention the diffusion of plasma 127 in the lower area of the chamber is suppressed, and the occurrence of particles is reduced.

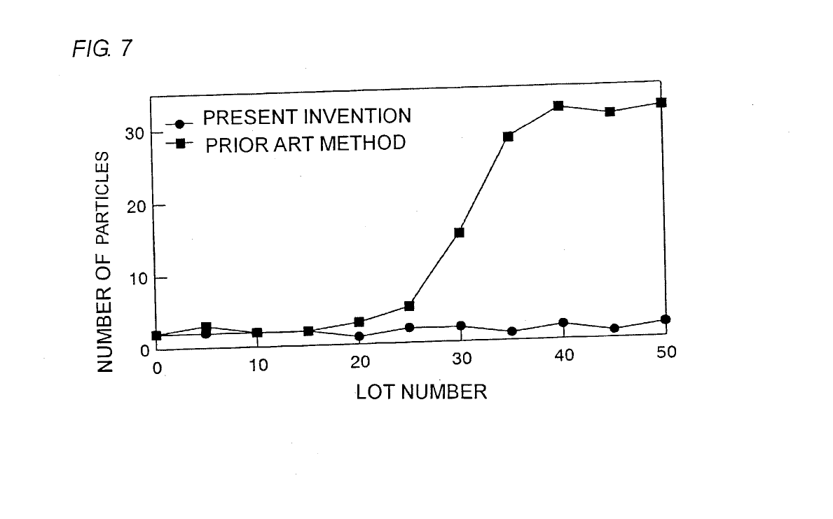

FIG. 7 is used to explain the relationship between the amount of particles and the process lot number according to the conventional system and the present invention. After processing 30 lots, the number of particles having a diameter of 0.2 μm or larger was 15 according to the conventional method, whereas the number was as small as two according to the present invention. Thus, by applying high frequency voltages with a phase difference of 180° to two opposing electrodes, and by covering or coating the side walls of the processing chamber and side surface of the electrode with polyimide, the amount of particles can be reduced greatly. Especially, the phase difference should be set to 180°±30° for best results.

According to the present invention, the high frequency voltage applied to two opposing electrodes is set to have a phase difference of 180°±30° so as to suppress the diffusion of plasma within the chamber, and the side walls of the chamber is coated with polyimide so as to reduce the deposition of particles on the side walls. Moreover, since according to the present invention the plasma potential is reduced compared to the conventional apparatus, the energy of ions being incident on the polyimide surface is small and causes very little sputtering. Therefore, the polyimide coating film has a long lifetime.

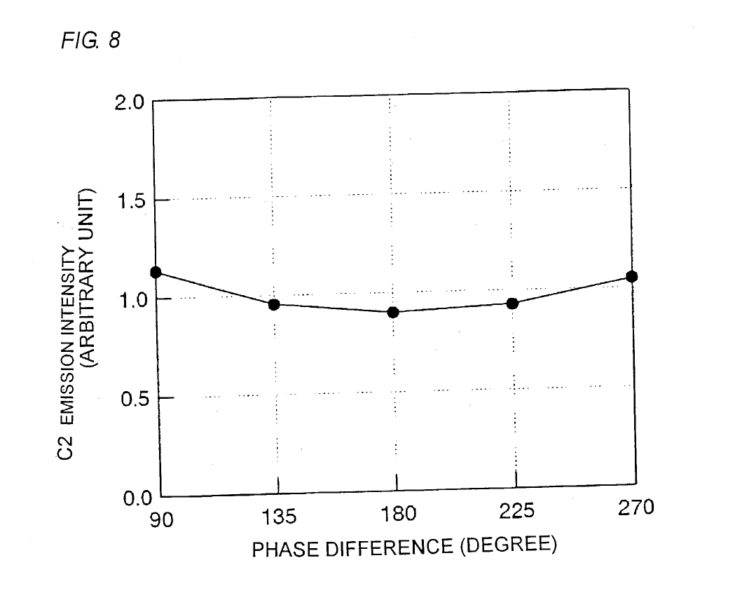

FIG. 8 explains the relationship between the plasma emission intensity of C₂ within the plasma and the phase difference. The plasma emission intensity of C₂ within the plasma shows the amount of carbon atoms in the plasma, and correlates with the etching performance such as mask selectivity and etch stop. According to FIG. 8, the plasma emission intensity of C₂ within the plasma is varied when the phase difference is changed. This shows that since the plasma potential is varied according to the phase difference, the energy of ions being incident on the carbon-containing film adhered on the side walls of the chamber is changed so that the amount of carbon radicals leaving the wall into the plasma is thereby changed. In order to perform etching of a very fine pattern, it is necessary to adjust precisely the composition of the plasma, but advantageously according to the present invention, even the minute plasma composition can be controlled not only by controlling the gas species and gas quantity but also by adjusting the phase difference.

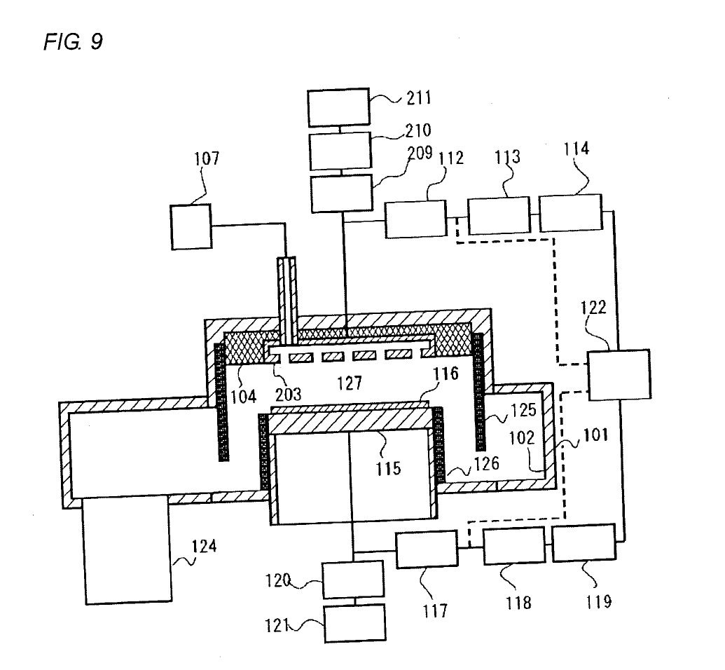

The second embodiment of the present invention will be explained with reference to FIG. 9. In the drawing, the elements that are equivalent to those of FIGS. 1 and 6 are marked with the same reference numbers, and detailed explanations thereof are omitted. The features unique to this drawing as compared to FIGS. 1 and 6 will be explained now. A cylindrical processing vessel 102, an upper electrode 203 formed of a conductor and disposed above a plate, and a dielectric body 104 are disposed airtightly on the upper opening portion of a vacuum vessel 101, defining therein a processing chamber. The upper electrode 203 is connected via a filter 209 and a matching unit 210 to a plasma generating power supply 211 of, for example, 27 MHz and 60 MHz. Plasma is generated by the high frequency power supplied through the upper electrode 203 into the processing vessel 102. Either covers including carbon (such as polyimide covers) 125 and 126, or inner walls having been coated with a film including carbon (such as inner walls having a polyimide coating) 125 and 126, are provided to the inner walls of the processing chamber. Similar to FIG. 6 illustrating the first embodiment, according to the present embodiment, high frequency voltages having a phase difference of 180° are applied to upper and lower electrodes 203 and 115, thereby keeping the plasma 127 at the upper area of the processing chamber. Thus, similar to the effect of embodiment 1, according to the present embodiment, the occurrence of foreign matter is effectively reduced by applying high frequency voltage having a phase difference of 180° to two opposing electrodes, and in addition, by covering or coating the side walls of the processing chamber and the side walls of the electrode with polyimide.

Moreover, according to the above embodiments the present invention is applied to an etching apparatus, but similar advantageous effects can be realized by applying the same to other plasma processing apparatuses such as ashing apparatus and plasma CVD apparatus where high frequency power is supplied to the wafer electrode.

According to the present invention where the plasma distribution is adjusted by controlling the phase of high frequency biases applied to the wafer electrode and to the electrode opposite thereto, the uniformity of etching can be effectively enhanced.

Even further, by controlling the phase of the high frequency bias, the impact of ions on the wall of the chamber can be controlled by the phase difference, by which the occurrence of particles from the inner wall of the apparatus can be reduced, which leads to longer cleaning cycles, and results in an improved throughput.

Moreover, the present invention controls the phase of the high frequency bias to thereby control the plasma composition, so high precision etching is made possible.

What is claimed is:

1. A plasma processing apparatus comprising:
a processing chamber to which is connected an evacuator for decompressing the inner space of the processing chamber;
a gas feeding apparatus for feeding gas into the processing chamber;
a wafer electrode on which is mounted an object to be processed;
an antenna electrode for generating plasma which is disposed so as to oppose to the wafer electrode;
a plasma-generating high frequency power supply connected to the antenna electrode;
a first high frequency power supply connected to the wafer electrode;
a second high frequency power supply connected to the antenna electrode; and
a phase control means for controlling a phase difference of two high frequencies having the same frequency and applied from the first high frequency power supply and the second high frequency power supply, respectively.

2. A plasma processing apparatus comprising:
a processing chamber to which is connected an evacuator for decompressing the inner space of the processing chamber;
a gas feeding apparatus for feeding gas into the processing chamber;
a wafer electrode on which is mounted an object to be processed;
an antenna electrode for generating plasma which is disposed so as to oppose to the wafer electrode;
a plasma-generating high frequency power supply connected to the antenna electrode;
a magnetic field generating means;
a first high frequency power supply connected to the plate electrode;
a second high frequency power supply connected to the antenna electrode; and
a phase control means for controlling a phase difference of two high frequencies having the same frequency and applied from the first high frequency power supply and the second high frequency power supply, respectively.

3. A plasma processing apparatus according to claim 1 or claim 2, wherein the phase difference of the high frequencies can be controlled within the range of 0° to 360°.

4. A plasma processing apparatus according to claim 1 or claim 2, further comprising a means for switching by steps the phase difference of the high frequencies while the object is being processed.

5. A plasma processing apparatus according to claim 1 or claim 2, further comprising a means for varying the phase difference of high frequencies with time.

6. A plasma processing apparatus according to claim 1 or claim 2, wherein an inner wall of the processing chamber is coated with a film containing carbon.

7. A plasma processing apparatus according to claim 1 or claim 2, wherein a cover containing carbon is disposed at an inner side of the processing chamber.

8. A plasma processing apparatus according to claim 1 or claim 2, wherein an innerwall of the processing chamber is coated with polyimide.

9. A plasma processing apparatus according to claim 1 or claim 2, wherein a cover formed of polyimide is disposed at an inner side of the processing chamber.

10. A plasma processing apparatus according to claim 1 or claim 2, wherein a surface of an inner side of the processing chamber is coated with an oxide of an element in the III A family of the periodic table.

11. A plasma processing method utilizing a plasma processing apparatus comprising a processing chamber to which is connected an evacuator for decompressing the inner space of the processing chamber; a gas feeding apparatus for feeding gas into the processing chamber; a wafer electrode on which is mounted an object to be processed; an antenna electrode for generating plasma which is disposed so as to oppose to the wafer electrode; a plasma-generating high frequency power supply connected to the antenna electrode; a first high frequency power supply connected to the plate electrode; and a second high frequency power supply connected to the antenna electrode; wherein
the plasma processing method comprises setting the frequency of the high frequency applied from the first high frequency power supply and that applied from the second high frequency power supply to be equal, and controlling the phase difference of the two high frequencies.

12. A plasma processing method according to claim 11, wherein the phase difference of the high frequencies is controlled within the range of 0° to 360°.

13. A plasma processing method according to claim 11, wherein the phase difference of the high frequencies is switched by steps while the object is being processed.

14. A plasma processing method according to claim 11, wherein the phase difference of the high frequencies is switched by steps within the range of 0° to 360° while the object is being processed.

15. A plasma processing method according to claim 11, wherein the phase difference of the high frequencies is varied with time.

16. A plasma processing method according to claim 11, wherein the phase difference of high frequencies is varied with time within the range of 0° to 360° while the object is being processed.
